(19) United States
(12) Patent Application Publication
(10) Pub. No.: US 2010/0243042 A1
(43) Pub. Date: Sep. 30, 2010

(54) HIGH-EFFICIENCY PHOTOVOLTAIC CELLS

(75) Inventor: Wei Shan, Fremont, CA (US)

Correspondence Address: BUCHANAN, INGERSOLL & ROONEY PC, POST OFFICE BOX 1404, ALEXANDRIA, VA, 22313-1404, US

(73) Assignee: JA Development Co., Ltd., Shanghai (CN)

(21) Appl. No.: 12/729,673

(22) Filed: Mar. 23, 2010

Related U.S. Application Data
(60) Provisional application No. 61/162,782, filed on Mar. 24, 2009.

(51) Int. Cl. H01L 31/075; H01L 31/18; H01L 31/0236

(52) U.S. Cl. 136/255; 438/71; 257/E31.13

(57) ABSTRACT

A high efficiency photovoltaic cell includes a single crystalline or multi-crystalline silicon substrate as an absorber and a selective emitter structure on the front of the absorber. On the back of the absorber is a laminate of intrinsic amorphous hydrogenated silicon, heavily doped amorphous hydrogenated silicon, a transparent conductive oxide and back metallic contact. A method of manufacturing this high efficiency photovoltaic cell includes texturing both surfaces of the absorber, forming the various layers and annealing the photovoltaic cell.

### CROSS-REFERENCE TO RELATED APPLICATION

This application claims priority under 35 U.S.C. §119 to U.S. Provisional Application No. 61/162,782, filed Mar. 24, 2009, the entire content of which is hereby incorporated by reference.

### BACKGROUND

Embodiments described herein are directed to the field of photovoltaics (PV) and are useful for conversion of solar energy directly into electrical energy. The embodiments are specifically related to device structures of photovoltaic cells (solar cells) fabricated on crystalline (mono- and multi-crystalline) silicon wafers with an object to enhance photovoltaic performance of the photovoltaic cells and achieve higher solar energy conversion efficiency, i.e. extracting more electrical power from a given solar irradiance.

Photovoltaics is a technology wherein large area p-n junction or hetero-junction diodes are used to convert sunlight into electricity. These diodes are therefore called photovoltaic cells. When a photovoltaic cell is exposed to the sunlight, photons of the sunlight having energy greater than the band gap of the semiconductor material(s) across the junction of the photovoltaic cell generate electron-hole pairs (photo-generated carriers) in the photovoltaic cell. The junction directs flow of different types (electrons or holes) of the photo-generated carriers to opposite directions due asymmetric characteristics of the junction, which generates useful electrical energy.

The theoretical energy conversion efficiency of a photovoltaic cell comprising only one p-n junction is about 30% [W. Shockley and H. J. Queisser, J. Appl. Phys. 32, 150 (1961)], which is a ratio of electrical power that can be theoretically generated from the photovoltaic cell to a solar radiant flux (radiant power) the photovoltaic cell receives. Among photovoltaic cells made from various materials, those made from single-crystalline silicon (mono-Si) are highly efficient and have low production cost. Other types of photovoltaic cells, such as those based on III-V or II-VI group hetero-junctions, can be more efficient than mono-Si photovoltaic cells but suffer from very high production cost and toxicity during production, use and disposal.

### SUMMARY

Described herein is a photovoltaic cell comprising: a single crystalline or multi-crystalline silicon substrate as an absorber, the absorber lightly doped to one conductivity type and having a front surface and a back surface; a selective emitter structure on the front surface of the absorber, the selective emitter structure having, a diffusion layer with heavily doped regions doped to an opposite conductivity type from the absorber, lightly doped regions disposed between the heavily doped regions and doped to an opposite conductivity type from the absorber, an antireflective layer, and a front metallic contact in electrical contact only with the heavily doped regions; an intrinsic a-Si:H layer covering essentially the entire back surface of the absorber; an a-Si:H layer heavily doped to the same conductivity type of the absorber, covering essentially the entire intrinsic a-Si:H layer; a transparent conductive oxide layer covering essentially the entire heavily doped a-Si:H layer; and a back metallic contact.

A method of manufacturing the photovoltaic cell is also provided, the method comprising: texturing both surfaces of the absorber; forming a selective emitter structure on the front surface of the absorber; smoothing the back surface of the absorber; sequentially depositing on the back surface of the absorber the intrinsic a-Si:H layer, the heavily doped a-Si:H layer, and the transparent conductive oxide layer; depositing the back metallic contact on the transparent conductive oxide layer; and annealing the photovoltaic cell.

### BRIEF DESCRIPTION OF FIGURES

FIG. 1 shows a cross-sectional schematic of a conventional photovoltaic cell.

FIG. 2 shows a cross-sectional schematic of a conventional photovoltaic cell with a selective emitter structure.

FIG. 3 shows a cross-sectional schematic of a photovoltaic cell according to a first embodiment.

FIG. 4 shows a cross-sectional schematic of a photovoltaic cell according to a second embodiment.

### DETAILED DESCRIPTION

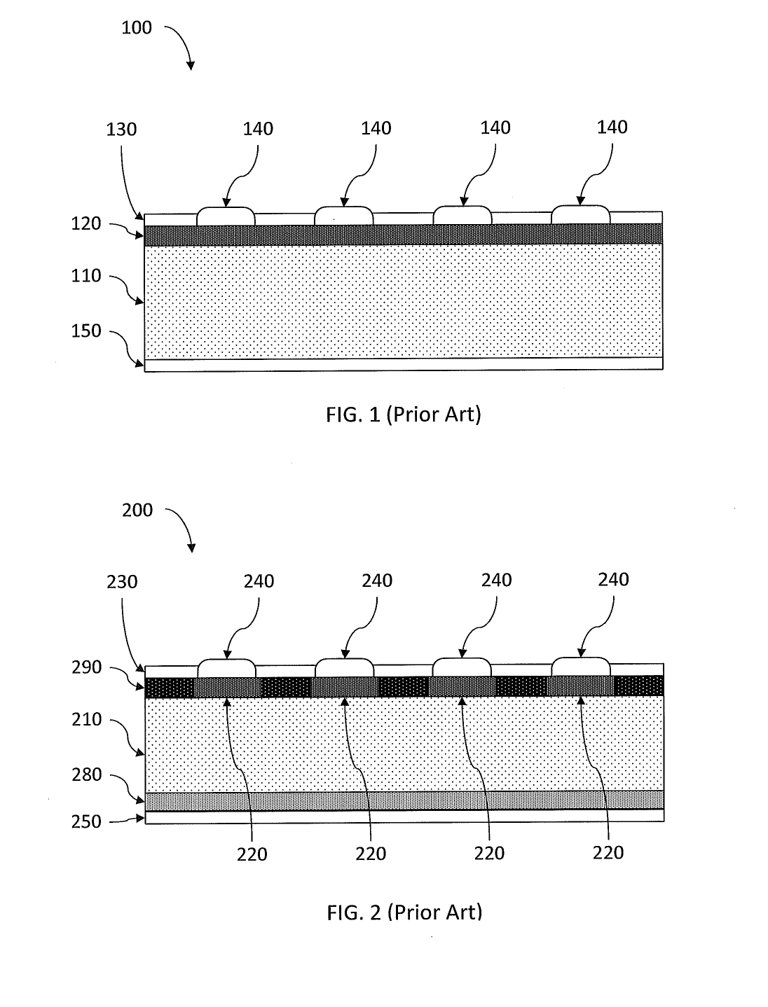

Mono-Si photovoltaic cells can be fabricated either on p-type single-crystalline Si substrates cut from boron-doped (B-doped) single-crystalline silicon ingots or on n-type single-crystalline Si substrates cut from phosphorus-doped (P-doped) single-crystalline silicon ingots produced by a method such as the Czochralski (CZ) growth method. FIG. 1 shows an exemplary structure of a mono-Si photovoltaic cell 100. The photovoltaic cell 100 has a single-crystalline p-type Si substrate that can absorb a large portion of the radiant flux the photovoltaic cell 100 receives and is thus called the absorber 110. Si is an indirect band-gap semiconductor material with weak absorption at long wavelengths. To enhance absorption at long wavelengths, the absorber 110 can be wet-chemical etched to form textured surfaces on both sides, preferably as a first step of manufacturing the photovoltaic cell 100. On a front surface of the absorber 110, a heavily doped (e.g., above 6×10¹⁷ dopant atoms/cm³) n-type layer (also know as n⁺ layer or emitter) 120 forms a p-n junction with the absorber 110. The emitter 120 can be a heavily doped (e.g. with phosphorus) low sheet-resistance diffusion layer to achieve a reasonably low contact resistance. An antireflective layer 130 (e.g., silicon nitride or silicon dioxide, or a stack comprising a silicon oxide layer and a silicon nitride layer) covers the emitter 120 and is effective to increase the amount of sunlight coupled into the photovoltaic cell 100 (i.e., antireflection). A front metallic contact 140 and a back metallic contact 150 (e.g., Al contact) can be made on the front and back surfaces of the photovoltaic cell, respectively. The front metallic contact 140 is often made as a group of thin fingers in order not to block too much incident sunlight.

Typical energy conversion efficiency of mass produced mono-Si photovoltaic cells made from B-doped p-type Si substrates is around 16-17%, which is primarily limited by recombination of photo-generated carriers. Recombination of photo-generated carriers can be induced by defects and impurities in the Si substrates and can adversely shorten lifetime of minority carriers (i.e. electrons in p-type silicon) in the p-type absorber. Recombination can also occur through a mechanism of surface recombination near front and back surfaces of the photovoltaic cell, as well as through Auger recombination in heavily doped regions.

Among the abovementioned recombination mechanisms, surface recombination can cause significant loss in the conversion efficiency of a Si photovoltaic cell. Loss due to surface recombination can be alleviated by passivation of silicon surfaces.

However, effective surface passivation on the emitter 120 can be difficult because the emitter 120 has a high surface concentration of dopant resulting from heavy doping. Heavy doping in the emitter 120 can also cause poor short-wavelength response and increase Auger recombination in the emitter 120 region. As shown in FIG. 2, a mono-Si photovoltaic cell 200 has an absorber 210. To enhance absorption at long wavelengths, the absorber 210 can be wet-chemical etched to form textured surfaces on both sides, preferably as a first step of manufacturing the photovoltaic cell 200. A structure called a selective emitter can be used to improve passivation and reduce surface recombination on a front surface of the absorber 210. The selective emitter structure has a diffusion layer with heavily doped regions 220 which are disposed underneath a front metallic contact 240 (e.g., a metallic grid) to provide low contact resistance thereto, and lightly doped regions 290 (e.g., below 10¹⁷ dopant atoms/cm³) disposed between the heavily doped regions 220. Both the lightly doped regions 290 and the heavily doped regions 220 are doped to the opposite conductivity type from the absorber 210 (i.e. if the absorber 210 is p-type, the regions 220 and 290 are n-type, and vice versa). The heavily doped regions 220 and the lightly doped regions 290 form a p-n junction with the absorber 210. An antireflective layer 230 (e.g. silicon nitride or silicon dioxide, or a stack comprising a silicon oxide layer and a silicon nitride layer) covers the heavily doped regions 220 and lightly doped regions 290 except at the front metallic contact 240. The front metallic contact 240 electrically contacts only the heavily doped regions 220. The heavily doped regions 220 have low contact resistance to the front metallic contact 240. The regions 220 only cover a small portion of the front surface and thus do not contribute significantly to surface recombination. The lightly doped regions 290 are easier to passivate and can greatly enhance spectral response of the photovoltaic cell 200 in the short-wavelength range. Adoption of the selective emitter structure can increase conversion efficiency by about one percent.

The back surface of the photovoltaic cell 200, however, has a back metallic contact 250 (e.g., Al contact) in direct contact with the absorber 210. Surface recombination in the vicinity of the back metallic contact 250 can significantly reduce the density of minority carriers therein and reduce the open circuit voltage of the photovoltaic cell 200. Adding a back-surface field (BSF) layer 280 heavily doped to the same conductivity type as the absorber 210 between the absorber 210 and the back metallic contact 250 helps to reduce the surface recombination to a certain extent by creating an energy barrier against diffusion of the minority carriers toward the back surface, but does little to prevent recombination near the full-cell-sized back metallic contact 250.

An object of the embodiments described herein is to reduce recombination near the back metallic contact and enhance conversion efficiency.

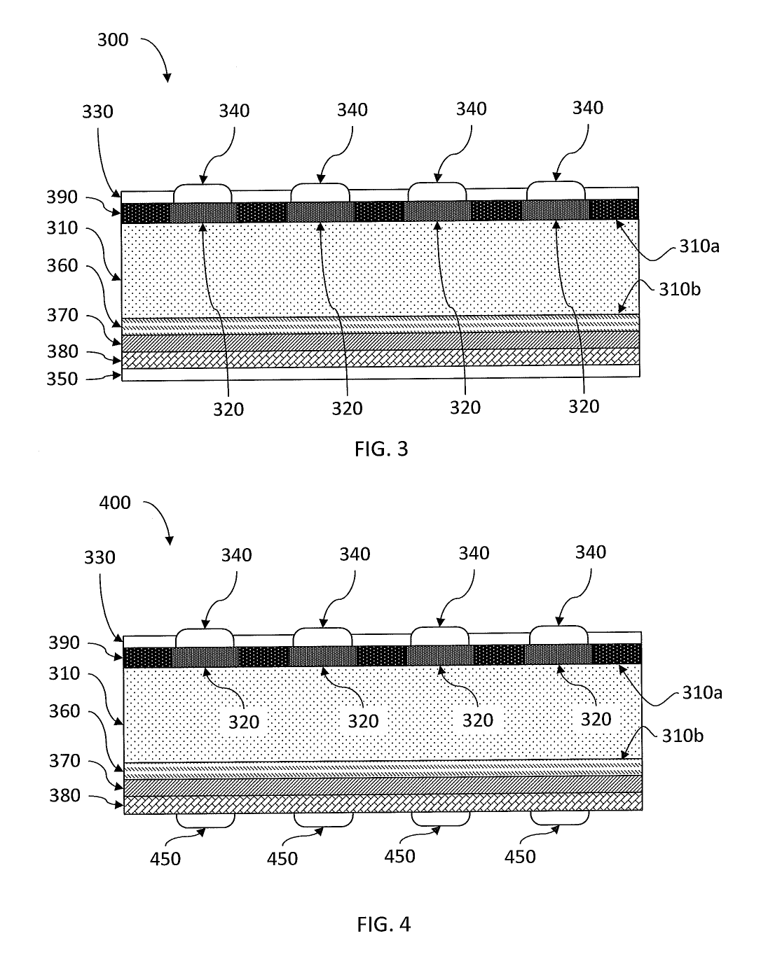

In a first embodiment, as shown in FIG. 3, a Si photovoltaic cell 300 has an absorber 310. The absorber 310 can be single crystalline Si or multi-crystalline Si wafer lightly doped to resistivity preferably from 0.1 to 10 Ohm·cm. To enhance absorption at long wavelengths, a front surface 310a of the absorber 310 can be textured. Disposed on the front surface of the absorber 310 is the selective emitter structure comprising a diffusion layer with heavily doped regions 320 which are disposed underneath a front metallic contact 340 (e.g. a metallic grid or metallic fingers) to provide low contact resistance thereto and with lightly doped regions 390 disposed between the heavily doped regions 320. Both the lightly doped regions 390 and the heavily doped regions 320 are doped to the opposite conductivity type from the absorber 310 (i.e., if the absorber 310 is p-type, the regions 320 and 390 are n-type, and vice versa). An antireflective layer 330 (e.g., silicon nitride or silicon dioxide, or a stack comprising a silicon oxide layer and a silicon nitride layer) covers the heavily doped regions 320 and the lightly doped regions 390 except where the front metallic contact 340 overlies the heavily doped regions 320. The front metallic contact 340 electrically contacts only the heavily doped regions 320. The photovoltaic cell 300 has a layer of intrinsic (substantially undoped) amorphous hydrogenated silicon (a-Si:H) 360 covering essentially an entire back surface 310b (preferably the entire back surface 310b) of the absorber 310, a layer of a-Si:H 370 heavily doped to the same conductivity type as the absorber covering essentially the entire intrinsic a-Si:H layer 360, a layer of transparent conductive oxide (TCO) 380 covering essentially the entire heavily doped a-Si:H layer 370, and a back metallic contact 350 (e.g., Al or Al/Ag alloy) covering essentially the entire TCO layer 380 and forming an Ohmic contact with the TCO layer 380. The back surface 310b of the absorber 310 is preferably smooth.

The photovoltaic cell 300 can be manufactured using a method comprising (1) texturing surfaces 310a and 310b of the absorber 310 using wet chemical etching; (2) forming the selective emitter structure on the front surface of the absorber 310 by cleaning the absorber 310, forming the diffusion layer by diffusing dopants of the opposite conductivity type from the absorber 310 to form the heavily doped regions 320 and lightly doped regions 390, depositing the antireflective layer 330 on areas of the diffusion layer not covered by the front metallic contact and forming the front metallic contact 340; (3) smoothing the back surface 310b of the absorber 310 using chemical polishing to completely remove any diffusion layer formed thereon during step (1), as well as to prevent the heavily doped regions 320 and lightly doped regions 390 from direct electrical contact with features to be made in step (4) below on the back surface 310b of the absorber 310; (4) sequentially depositing on the back surface 310b of the absorber 310 the intrinsic a-Si:H layer 360, the heavily doped a-Si:H layer 370, the TCO layer 380 and the back metallic contact 350; and (5) optionally annealing the photovoltaic cell 300. The intrinsic a-Si:H layer 360 and the heavily doped a-Si:H layer 370 can be deposited by a method such as plasma enhanced chemical vapor deposition (PECVD) or hot-wire deposition. Non-limiting examples of a solution (e.g., aqueous solution) suitable for the chemical polishing include KOH, NaOH, tetramethylammonium hydroxide (TMAH), and/or ethylenediamine (H₂NCH₂CH₂NH₂). The concentration of the solution is preferably from 10% to 40%. The temperature of the solution is preferably maintained at from 50° C. to 90° C. during the chemical polishing. The solution is more preferably an aqueous solution of 10% to 40% NaOH, or 10% to 40% KOH, or 10% to 30% tetramethylammonium hydroxide, or 10% to 30% ethylenediamine. The intrinsic a-Si:H layer 360 and the heavily doped a-Si:H layer 370 are preferably deposited by the same deposition method except that a dopant species such as phosphorus (to achieve n-type conductivity) or boron (to achieve p-type conductivity) is added during deposition of the heavily doped a-Si:H layer 370. The a-Si:H layers 360 and 370 preferably have thicknesses from 1 to 50 nm. Temperature during deposition of layers 360 and 370 is preferably at most 200° C., more preferably from 100 to 200° C. The TCO layer 380 can be indium tin oxide (ITO) or aluminum doped zinc oxide with a thickness of 10 to 200 nm, deposited by physical vapor deposition (PVD). The back metallic contact 350 can be a thick layer (preferably 1 to 20 microns) of aluminum or aluminum/silver alloy deposited by screen printing or PVD. In this embodiment, the back metallic contact 350 preferably covers an entire back surface of the photovoltaic cell 300. The photovoltaic cell 300 is preferably annealed at about 200 to 300° C. to reduce resistivity of the contacts 340 and 350.

Advantages of the photovoltaic cell 300 include that (a) the intrinsic a-Si:H layer 360 provides excellent surface passivation on the absorber 310 and thus minimizes recombination velocity for minority carriers in the vicinity of the back metallic contact 350; (b) the combination of the intrinsic a-Si:H layer 360, the doped a-Si:H layer 370, the TCO layer 380 and the back metallic contact 350 are functional as a high reflector that can lead to better light trapping than in a photovoltaic cell with a conventional back metallic contact in direct contact with a crystalline Si absorber; (c) the doped a-Si:H layer 370 induces an energy barrier confining minority carriers to the lightly doped absorber 310 and thus can greatly enhance the spectral response at low photon energies (i.e., at long-wavelength range of the solar spectrum) and increase the open circuit voltage of the photovoltaic cell 300.

FIG. 4 shows a photovoltaic cell 400 according to a second embodiment. The photovoltaic cell 400 is identical to the photovoltaic cell 300, except that the photovoltaic cell 400 has a back metallic contact 450 comprising a discrete metallic pattern that corresponds to a pattern (e.g., grid or fingers) of the front metallic contact 340 in the selective emitter structure. The photovoltaic cell 400 can be made by the same manufacturing method as the photovoltaic cell 300. Compared to the photovoltaic cell 300, the photovoltaic cell 400 can have a higher conversion efficiency by capturing diffusive sunlight from its back surface.

While the photovoltaic cell and its method of manufacture have been described in detail with reference to specific embodiments thereof, it will be apparent to those skilled in the art that various changes and modifications can be made, and equivalents employed, without departing from the scope of the appended claims.

What is claimed is:

1. A photovoltaic cell comprising:
a single crystalline or multi-crystalline silicon substrate as an absorber, the absorber lightly doped to one conductivity type and having a front surface and a back surface;
a selective emitter structure on the front surface of the absorber, the selective emitter structure having, a diffusion layer with heavily doped regions doped to an opposite conductivity type from the absorber, lightly doped regions disposed between the heavily doped regions and doped to an opposite conductivity type from the absorber, an antireflective layer, and a front metallic contact in electrical contact only with the heavily doped regions;
an intrinsic a-Si:H layer covering essentially the entire back surface of the absorber;
an a-Si:H layer heavily doped to the same conductivity type of the absorber, covering essentially the entire intrinsic a-Si:H layer;
a transparent conductive oxide layer covering essentially the entire heavily doped a-Si:H layer; and
a back metallic contact.

2. The photovoltaic cell of claim 1, wherein the front surface is textured and the back surface is smooth.

3. The photovoltaic cell of claim 1, wherein the antireflective coating covers the diffusion layer except where the front metallic contact overlies the heavily doped region and the antireflective coating is silicon nitride or titanium oxide.

4. The photovoltaic cell of claim 1, wherein the back metallic contact is made of aluminum or an aluminum-silver alloy.

5. The photovoltaic cell of claim 1, wherein the back metallic contact is 1 to 20 microns thick.

6. The photovoltaic cell of claim 1, wherein the transparent conductive oxide layer is indium tin oxide or aluminum doped zinc oxide.

7. The photovoltaic cell of claim 1, wherein the back metallic contact covers an entire back surface of the photovoltaic cell.

8. The photovoltaic cell of claim 1, wherein the back metallic contact is a discrete pattern corresponding to a pattern of the front metallic contact.

9. The photovoltaic cell of claim 1, wherein the intrinsic a-Si:H layer and the heavily doped a-Si:H layer have thicknesses from 1 to 50 nm.

10. The photovoltaic cell of claim 1, wherein the absorber has a resistivity from 0.1 to 10 Ohm·cm and the conductivity type of the absorber is p-type or n-type.

11. A method of manufacturing the photovoltaic cell of claim 1, the method comprising:
texturing both surfaces of the absorber;
forming the selective emitter structure on the front surface of the absorber;
smoothing the back surface of the absorber to completely remove any diffusion layer formed thereon during the forming of the selective emitter structure;
sequentially depositing on the smoothed back surface of the absorber the intrinsic a-Si:H layer, the heavily doped a-Si:H layer, and the transparent conductive oxide layer;
depositing the back metallic contact on the transparent conductive oxide layer; and
annealing the photovoltaic cell.

12. The method of claim 11, wherein the back surface is smoothed by chemical polishing with an aqueous solution of KOH, NaOH, tetramethylammonium hydroxide, and/or ethylenediamine, wherein the solution is maintained at 50° C. to 90° C.

13. The method of claim 12, wherein the aqueous solution is 10% to 40% NaOH, or 10% to 40% KOH, or 10% to 30% tetramethylammonium hydroxide, or 10% to 30% ethylenediamine.

14. The method of claim 11, wherein the intrinsic a-Si:H layer and the heavily doped a-Si:H layer are deposited by the same deposition method except that a dopant species is added during deposition of the heavily doped a-Si:H layer.

15. The method of claim 11 wherein the intrinsic a-Si:H layer and the heavily doped a-Si:H layer are deposited by PECVD or hot wire deposition at a temperature from 100 to 200° C.

16. The method of claim 11, wherein the transparent conductive oxide layer is deposited by physical vapor deposition.

17. The method of claim 11, wherein the back metallic contact is deposited by screen printing or physical vapor deposition.

18. The method of claim 11, wherein the photovoltaic cell is annealed at a temperature from 200 to 300° C.

19. The method of claim 11, wherein the conductivity type of the absorber and the heavily doped a-Si:H layer is p-type; wherein a thickness of the intrinsic a-Si:H layer and a thickness of the heavily doped a-Si:H layer is each from 1 to 50 nm and a thickness of the back metallic contact is from 1 to 20 microns.

20. The method of claim 11, wherein the conductivity type of the absorber and the heavily doped a-Si:H layer is n-type; wherein a thickness of the intrinsic a-Si:H layer and a thickness of the heavily doped a-Si:H layer is each from 1 to 50 nm and a thickness of the back metallic contact is from 1 to 20 microns.
